(19) United States
(12) Patent Application Publication
(10) Pub. No.: US 2023/0195949 A1
(43) Pub. Date: Jun. 22, 2023

(54) NEURAL OPERATORS FOR FAST WEATHER AND CLIMATE PREDICTIONS

(71) Applicant: International Business Machines Corporation, Armonk, NY (US)

(72) Inventors: Komminist Weldemariam, Ottawa (CA); Björn Lütjens, Cambridge, MA (US); Campbell D Watson, Brooklyn, NY (US); Alberto Costa Nogueira Junior, Campinas (BR); Simon Holgate, Liverpool (GB); Catherine H. Crawford, Bedford, NH (US)

(21) Appl. No.: 17/557,666

(22) Filed: Dec. 21, 2021

(51) Int. Cl. G06F 30/10; G06F 30/27; G06N 3/08

(52) U.S. Cl. CPC G06F 30/10; G06F 30/27; G06N 3/08

(57) ABSTRACT

Initial and boundary conditions, and parameters associated with geophysical modeling can be received. Based on the received initial and boundary conditions and parameters, a multiscale model can be trained for data generation to produce first resolution simulation data and second resolution simulation data for a surrogate machine learning model training, where the second resolution simulation data has higher resolution than the first resolution simulation data. A surrogate model can be created using neural operators, where the surrogate model is trained using the first resolution simulation data and second resolution simulation data. An operational forecasting model can be generated using the surrogate model.

### BACKGROUND

The present application relates generally to computers and computer applications, and more particularly to physical modeling such as geophysical modeling, neural networks and neural operators.

The impacts of climate change are expected to grow, in size, complexity and number in the coming decades. Climate impacts such as storm surge are simulated by geophysical partial differential equation (PDE) models, but are often infeasible to run at the resolution useful for many applications due to computational expense. For instance, storm surge models can be computationally too expensive for uncertainty quantification, e.g., for example, on most conventional computers. For example, approximating PDEs with neural networks may assume near-infinite training data. While conventional surrogate models can be computationally lightweight, they may not capture certain nonlinear dynamics. Further, while neural network-based surrogate models may capture certain nonlinear dynamics, they may need to be retrained for every set of parameters.

### BRIEF SUMMARY

The summary of the disclosure is given to aid understanding of a computer system and method of providing neural operators for modeling, and not with an intent to limit the disclosure or the invention. It should be understood that various aspects and features of the disclosure may advantageously be used separately in some instances, or in combination with other aspects and features of the disclosure in other instances. Accordingly, variations and modifications may be made to the computer system and/or their method of operation to achieve different effects.

A computer-implemented method in an aspect can include receiving initial and boundary conditions, and parameters associated with geophysical modeling. The method can also include, based on the received initial and boundary conditions and parameters, running a multiscale model for data generation to produce first resolution simulation data and second resolution simulation data for a surrogate machine learning model training. The second resolution simulation data can have higher resolution than the first resolution simulation data. The method can also include creating a surrogate model using neural operators, where the surrogate model is trained using the first resolution simulation data and second resolution simulation data. The method can also include generating an operational forecasting model using the surrogate model.

A system, in an aspect, can include a processor and a memory device coupled with the processor. The processor can be configured to receive initial and boundary conditions, and parameters associated with geophysical modeling. The processor can also be configured to, based on the received initial and boundary conditions and parameters, run a multiscale model for data generation to produce first resolution simulation data and second resolution simulation data for a surrogate machine learning model training, where the second resolution simulation data has higher resolution than the first resolution simulation data The processor can also be configured to create a surrogate model using neural operators, wherein the surrogate model is trained using the first resolution simulation data and second resolution simulation data. The processor can also be configured to generate an operational forecasting model using the surrogate model.

A computer readable storage medium storing a program of instructions executable by a machine to perform one or more methods described herein also may be provided.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 is a diagram illustrating a super-parametrization framework in an embodiment.

FIG. 2 is a diagram showing low-resolution processes embedded with high-resolution processes for implementing neural operators with super-parametrization in an embodiment.

FIG. 3 is a diagram illustrating training data generation in an embodiment.

FIG. 4 is a diagram illustrating surrogate model creation in an embodiment.

FIG. 5 is a diagram illustrating operational forecasting in an embodiment.

FIG. 6 is a diagram illustrating storm surge modeling in a climate impact modeling framework in an embodiment.

FIG. 7 shows system architecture in an embodiment.

FIG. 8 is a flow diagram illustrating a method in an embodiment.

FIG. 9 is a diagram showing components of a computer system in one embodiment that can intelligently combine neural operators with super-parametrization to infer fine scale processes in multiscale models.

FIG. 10 illustrates a schematic of an example computer or processing system that may implement a system according to one embodiment.

FIG. 11 illustrates a cloud computing environment in one embodiment.

FIG. 12 illustrates a set of functional abstraction layers provided by cloud computing environment in one embodiment of the present disclosure.

### DETAILED DESCRIPTION

In an embodiment, a system and/or method can intelligently speed up geophysical PDE models.

For instance, in an embodiment, a new PDE solver for multiscale modeling can be provided by combining the super-parametrization (SP) with flexible neural operators. Multiscale super-parametrization can provide for high-resolution models embedded within a lower-resolution model.

A parametrization estimates parameter values without explicitly simulating the processes directly. Parametrizations can be referred to as low order models. Super-parametrization replaces one or more parametrizations with another model that can be designed to simulate the processes explicitly, e.g., to provide more accurate parameter values back to the main model.

Neural operators generalize neural networks that map between finite-dimensional Euclidean spaces to neural networks that map between infinite dimensional function spaces.

In an embodiment, the system and/or method may combine physics with artificial intelligence to speed up the simulation of high-resolution storm surge. In an embodiment, such modeling can provide for faster surge model predictions for uncertainty propagation, parameter inference, real-time inference and democratized access. In an embodiment, the modeling methodology can be integrated with a modeling framework such as Climate Impact Modeling Framework (CIMF) from International Business Machines Corporation, Armonk, New York, and enhance operational impact models such as flood models. In another embodiment, the modeling methodology can be integrated with other modeling framework such as those implementing PDE models in disease modeling.

In an embodiment, a system and/or method may provide for the combination of super-parametrization (embedding high-resolution model in a lower-resolution model) with neural operators (e.g., neural networks operating in reduced order or Fourier space). Super-parametrization or SP can provide more accurate parameter values back to the main host or low-resolution model (e.g., information about convective mass flux). SP can be more accurate than traditional parametrizations and computationally cheaper than running the full domain at high-resolution. In an embodiment, the high-resolution model can be approximated with a neural network. This neural network can be more generalizable if it is operating in reduced order or Fourier space as in a neural operator. For instance, creating a surrogate of the SP with a neural operator allows for application across different mesh resolutions and parameter sets (e.g., changes in very uncertain cloud physics parameters).

A super-parametrization is a type of multi-scale modeling framework. In an embodiment, machine learning (ML) or neural networks in reduced order or Fourier space, e.g., neural operators, can be used with the super-parametrization. For instance, ML or neural networks can approximate the simulated parameters in a high-resolution model.

In an embodiment, the system and/or method approximates the high-resolution parameters which are then fed back to the low-resolution model, which remains modeled as is, e.g., not approximated. A benefit of such methodology can be that the system and/or method can retain the skill of a numerical modeling system for large scale dynamics as it simulates the lower-resolution system. The system and/or method can replace expensive high-resolution simulations with neural networks — that also operate in reduced order or Fourier space — to provide information at fine scales to the lower-resolution model. This approach can create an improved representation of fine scale processes and its framing as a multi-scale SP framework makes neural network training tractable.

A system and/or method in an embodiment can intelligently combine neural operators with super-parametrization to rapidly infer fine scale processes in multiscale models. For example, a method in an embodiment can include running a multiscale model (e.g., coupled low resolution and high resolution models), e.g., using one or more traditional PDE solvers, for data generation to produce low and high-resolution simulation data for artificial intelligence (AI) machine learning (ML) surrogate training. The method can also include creating a surrogate model using neural operators and training the surrogate model (e.g., neural operator) with the data generated, e.g., to emulate a high resolution model). The multiscale model (coupled low resolution and high resolution models) can be run using, e.g., traditional PDE solvers for low resolution and the surrogate model (e.g., learning-based PDE solver) for high resolution. The method can also include generating an operational forecasting model using the surrogate model. The method can also include solving PDEs that work on all multiscale modeling formulations. The method can also include learning PDEs family over all parameters using the neural operators.

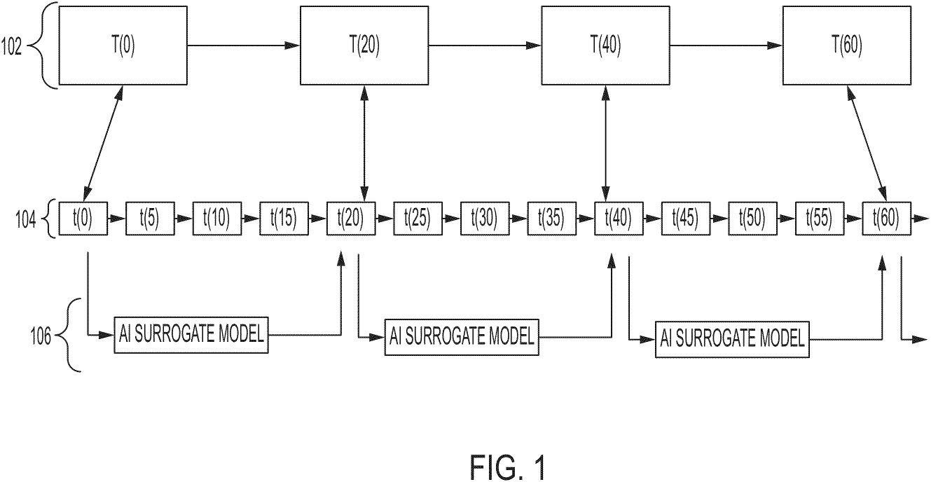

In an embodiment, multiscale super-parametrization includes allowing models inside models. FIG. 1 is a diagram illustrating a super-parametrization framework in an embodiment. At 102, a low-resolution model simulation, for example, modeling ocean currents, is shown. For instance, the model simulation 102 shows modeling of ocean currents at time intervals t(0), t(20), t(40), t(60), et seq. At 104, a high-resolution model simulation, for example, modeling the ocean currents, is shown. For instance, the model simulation 104 shows modeling ocean currents at finer or higher resolution than at 102, e.g., modeling of the ocean currents at time intervals t(0), t(5), t(10), t(15), t(20), t(25), t(30), t(35), t(40), t(45), t(50), t(55), t(60). The process of such higher resolution modeling at 104 can be accelerated or sped up with artificial intelligence (AI) surrogate models 106 trained to emulate the high resolution model simulation. In this way, for example, super-parametrization simulation can be accelerated.

Neural operators map parameters to solutions, while conventional neural networks map space-time to the solution. In an aspect, a neural operator can be expressed as follows.

$${G}_{\text{Θ}} : {H}_{a} \left(D ; {ℝ}^{{d}_{a}}\right) \to {H}_{u} \left(D ; {ℝ}^{{d}_{u}}\right)$$

where,
G_{Θ}) represents neural network weights,
H in Hₐ represents function space (Banach),
α in Hₐ represents PDE parameter function, e.g., initial conditions (ICs), boundary conditions (BCs), parameters, forcing terms,
dₐ represents dimensionality of parameters,
H in Hᵤ represents function space of solutions,
u in Hᵤ represents solution,
D represents spatio-temporal domain, and
dᵤ represents dimensionality of solution.

In an embodiment, a system and/or method disclosed herein combine neural operators with super-parametrization. For instance, the following equation shows a low resolution model:

$$\frac{\tilde{u} \left(x , t\right)}{δ t} = - {\tilde{\text{N}}}_{x} \left[\tilde{u} \left(x , t\right) ; \tilde{a}\right] + \tilde{f} \left({G}_{Θ} \left(a\right) \left(x , t\right)\right)$$

where,
represents dynamics,
Ñₓ represents (non-)linear spatial differential operator,
ũ(x, t) represents low resolution solution,
ã represent low resolution parameters,
f̃ represents subgrid forcing term, and
G_{Θ} (a) (x, t) represents neural operator.

The following equation shows a high resolution model:

$$\frac{{G}_{\text{Θ}} \left(a\right) \left(x , t\right)}{δ t} = - N {}_{x} \left({G}_{\text{Θ}} \left(a\right) \left(x , t\right) ; a\right) + f \left(\tilde{u} \left(x , t\right)\right)$$

In this way, for example, the system and/or method may reduce training data to high-resolution domain; can perform mesh-free interpolation in location, z; and generalize to across parameter space, a.

In an embodiment, a PDE solver can be provided that works on all multiscale modeling formulations and is faster (e.g., 100-1000 times faster) than traditional PDE solvers. In this way, for example, a processing power requirement of a processor or computer can be reduced, and the speed of machine learning can be improved. A system, for example, combines neural operators with super-parametrization to rapidly infer the fine scale processes in multiscale models and feed them back to the large-scale dynamics. Neural operators improve upon existing super-parametrization implementations by learning the PDE family over all parameters, e.g., without a need for retraining when parameters or mesh change. Super-parametrization improves upon existing neural operator implementations by reducing the amount of data required for neural operator training. In an embodiment, a trained AI surrogate model can be combined with impact models (e.g., coastal flood) for risk assessment. An embodiment of a system and/or method can use AI surrogate models in place of the high-resolution models.

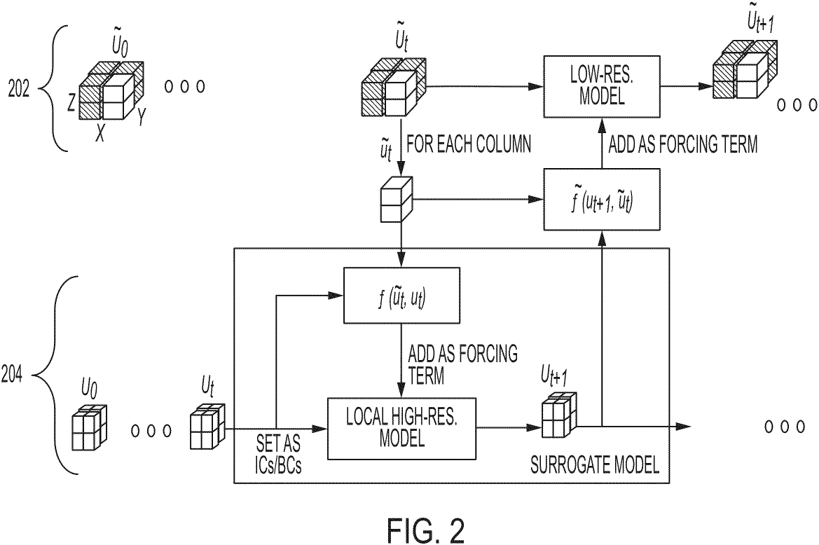

FIG. 2 is a diagram showing low-resolution processes embedded with high-resolution processes for implementing neural operators with super-parametrization in an embodiment. In an embodiment, a neural network-based surrogate of a high-resolution model is created and embedded within a low-resolution model. In an embodiment, a physics-based PDE model simulates low-resolution processes and is embedded with AI surrogates for high-resolution processes, also known as a super-parametrization framework with AI. Low resolution simulation is shown at 202. High resolution surrogate is shown at 204. For example, the surrogate 204 is implemented at higher resolution than the simulation at 202. In an embodiment, super-parametrizations resolve subgrid processes in low-resolution models by running high-resolution models in each grid cell. For example, the grid cells represent the spatial granularity of the model: the input, the analysis, and the output values are considered uniform across one grid cell. In the multiscale modeling framework shown in FIGS. 2, 202 has lower spatial granularity than 204. U₀ is the model state at time = 0 (initial time). When the model integrates forward in time (t) the model state is Ut. In FIG. 2, U and u are the model states of the low resolution 202 and high resolution 204 models respectively. u-tilde(t) is model state from U at time=t for the grid cells that spatially correspond to u. f(...) are the functions used to integrate the model forward in time. ICs are initial conditions from u(t) used within f(...) to integrate forward to u(t+1). BCs are boundary conditions from u-tilde(t) used within f(...) to integrate forward to u(t+1).

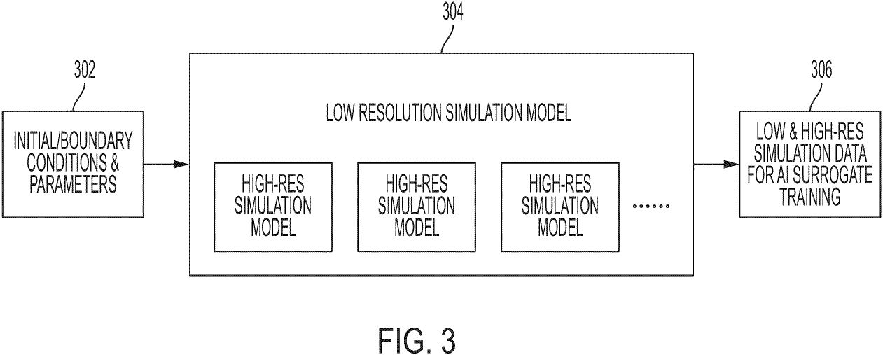

In an embodiment, a workflow for super-parametrization framework can include training data generation, surrogate model creation and operational forecasting. FIG. 3 is a diagram illustrating training data generation in an embodiment. At 302, initial and/or boundary conditions and parameters can be received. Examples of such conditions and parameters can be different for different types of models, and can include, but are not limited to, sea surface height, bathymetry, wind forcing, tidal processes, sea surface temperatures, and/or others.

At 304, one or multiple high-resolution models (e.g., FIGS. 2, 204) simulating high-resolution processes is/are embedded within the low-resolution model (e.g., FIGS. 2, 202) which simulates low-resolution processes. The low-resolution model may cover a large spatial extent and have multiple high-resolution models embedded at discrete locations to simulate the local processes at high-resolution. The embedded high-resolution models receive information from the low-resolution model at time t and the low-resolution model then receives information from the high-resolution models at time t+1. This process is repeated until the simulation ends.

The super-parametrization framework at 304 produces low and high resolution simulation data for AI surrogate training 306. An example of this simulation data can include the atmospheric temperature, humidity, wind speed and wind direction. Another example of this simulation data can be the sea level height.

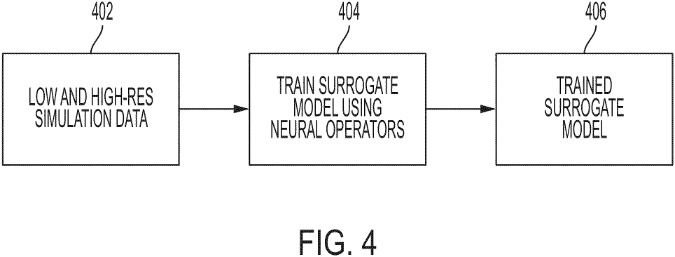

FIG. 4 is a diagram illustrating surrogate model creation in an embodiment. At 402, the low and high resolution simulation data (e.g., generated at 306) is input to a surrogate model with neural operators. In an embodiment, the surrogate model with neural operators can have known neural operator framework, for example, with integral kernel operators and a hidden layer construction. At 404, the surrogate model with neural operators is trained (e.g., a PDE solver), producing a trained surrogate model at 406.

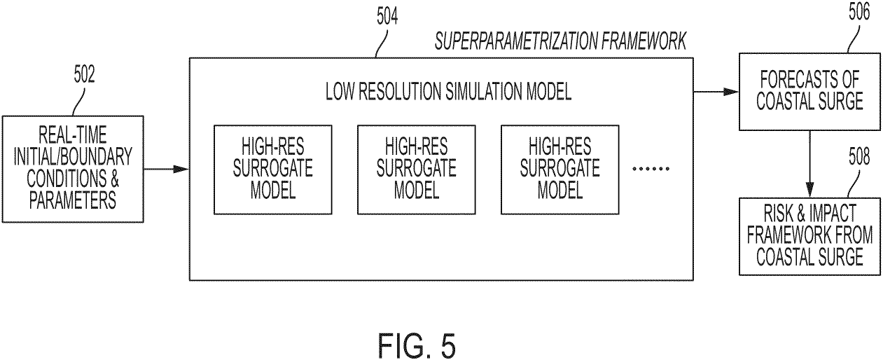

FIG. 5 is a diagram illustrating operational forecasting in an embodiment. Real time initial and/or boundary conditions and parameters are received at 502 and input to the super-parametrization framework 504 (e.g., a PDE solver). The super-parametrization framework 504 runs the low resolution simulation model and one or more trained surrogate models, which are able to handle high resolution data, and makes a forecast or prediction, e.g., a forecast of coastal surge at 506. In an embodiment, the forecast 506 can be input to another framework or model (e.g., risk and impact framework), which may determine a risk and/or impact using the predicted coastal surge 508.

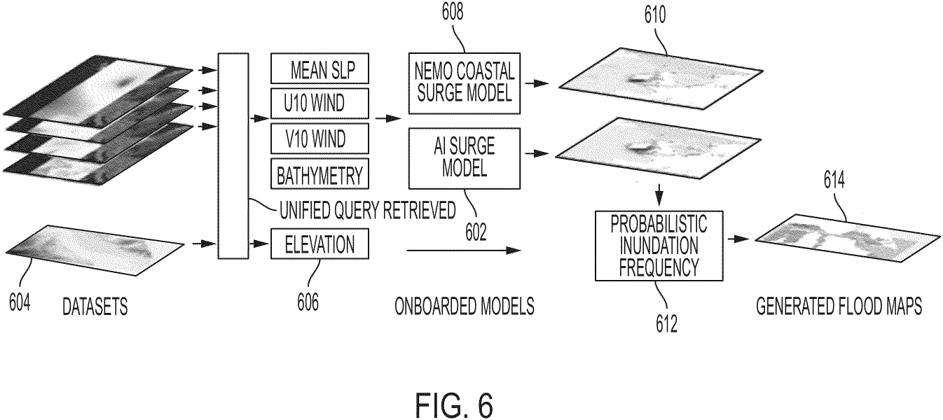

FIG. 6 is a diagram illustrating storm surge modeling in a climate impact modeling framework in an embodiment. A neural operator for storm surge surrogate modeling can be implemented in the component shown at 602. Datasets 604 can be received for modeling climate. At 606, data can be retrieved from the datasets 604, e.g., by querying the datasets. Models can be built for climate modeling. For example, 602 shows a storm surge surrogate model disclosed herein. Another model can be a framework for oceanographic, forecasting and climate studies 608. 610 shows example maps generated by the models in 608 and 602. For example, the maps 610 can be maps of flood depth changing over time. As another example, the maps 610 can be maps of atmospheric temperature. 612 shows the likelihood of some threshold (e.g., predefined threshold) being exceeded based on the maps in 610. For example, the probabilistic inundation frequency 612 can specify the likelihood that the flood depth exceeds 2 meters. Based on 612, flood maps 614 can be generated and visualized.

In one or more embodiments, predictions for multi-scale geophysical fluid models can be provided. In an embodiment, in a surrogate model for flood inundation, target can be water inundation height over land as simulated by a coastal inundation model; boundary conditions (features) can be sea surface height, bathymetry. In an embodiment, in a surrogate model for storm surge, target can be sea surface height as simulated by a storm surge model; boundary conditions (features) can be wind forcing, tidal processes. In an embodiment, in a surrogate model for hurricane models, target can be hurricane track as simulated by a hurricane model; boundary conditions (features) can be sea surface temperatures from global climate models.

In one or more embodiments, ensemble forecasts and real time application predictions can be made for long-term climate statistics and short-term weather outcomes. In an embodiment, a surrogate model can be implemented to create ensemble forecasts by running the fast surrogate model from known distributions of boundary conditions (e.g., wind forcing) and querying the output (e.g., sea surface height). In an embodiment, a surrogate model can be implemented to create real-time forecasts by running the fast surrogate model for a real-time observation of a boundary condition (e.g., wind forcing) and querying the output (e.g., sea surface height).

In one or more embodiments, methods and systems may intelligently combine neural operators with super-parametrization to rapidly infer fine scale processes in multiscale models. In an embodiment, the training data can be created by PDE-based numerical models for low and high resolution, which can use traditional PDE solvers. The data from this high-resolution model is then used to train a surrogate model, e.g., a neural operator. Examples of high resolution and low resolution data include, but are not limited to, atmospheric conditions like air temperature and height humidity, wind speed and direction. Another example can be the sea surface height. The method can also include creating a surrogate model using neural operators. The method can also include generating an operational forecasting model using the surrogate model. For example, the operational forecasting model can be 602 or 608 shown in FIG. 6, e.g., onboarded models. These models can be part of an architecture or framework that provides real-time data for initial and boundary conditions, then executes the models 602 and/or 608, provides or creates maps 610 and likelihood data 612, and produces forecasted flood maps 614 for a selected region. In an embodiment, the forecasting model is operational, e.g., the forecasting framework runs regularly, e.g., every 24 hours to produce forecasts. In an embodiment, a PDE solver (e.g., FIGS. 3, 304) may work on all multiscale modeling formulations. In an embodiment, the method can also include learning PDE families over all parameters using the neural operators. In an embodiment, the method can also include intelligently reducing the amount of data required for neural operator training using super-parametrization. In an embodiment, the surrogate model that is learned or trained can capture high-frequency features while maintaining low inference time through using AI-based methods. In an embodiment, the method can also include combining the trained AI surrogate model with impact models (e.g., coastal flood) for risk assessment.

The systems and methods can provide for rapid storm surge predictions at high-resolution with value to, for example, impact assessments, resiliency planning optimization, decision making. The systems and methods use lower compute consumption, which reduces energy usage and carbon footprint. Rapid storm surge predictions enable two-way interaction with downstream models, enabling better planning and response. Large volumes of storm surge predictions enable better uncertainty quantification and scenario exploration with value to, e.g., impact assessments, planning optimization.

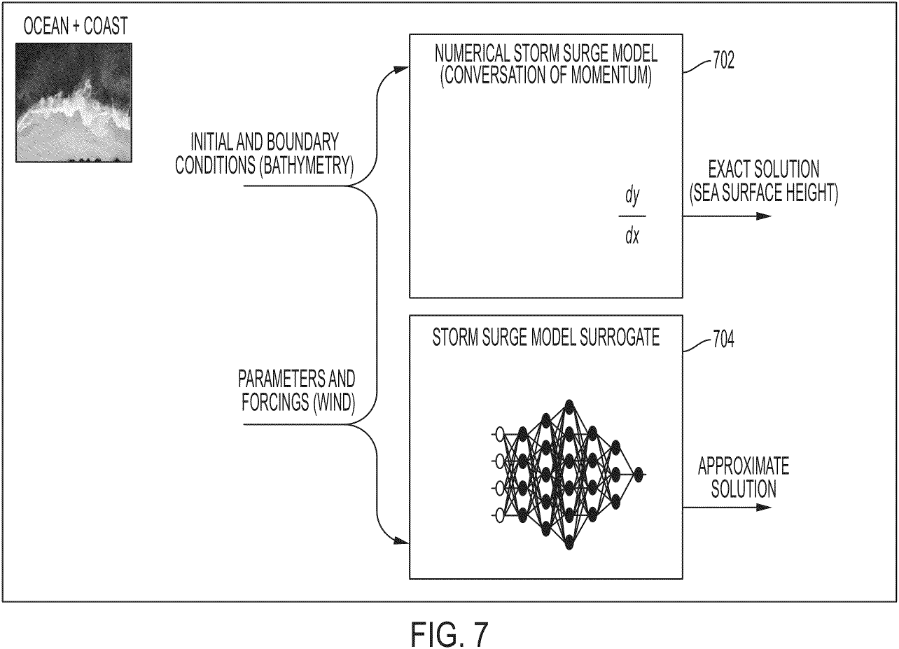

FIG. 7 shows system architecture in an embodiment. A lightweight surrogate model (of high-resolution dynamics) can be built. For example, the model can be queried for different wind conditions. In an embodiment, such a system can leverage a multi-scale formulation to reduce the size of the training dataset. For example, a surrogate storm surge model 704 with a neural operator can be created. Initial and boundary conditions such as bathymetry, and parameters and forcings such as wind can be input to the models for output a solution. Two types of models 702 and 704 are shown for simulating a dynamical system, in this example case, storm surge. For example, the model 702 uses a traditional PDE solver (e.g., Nucleus for European Modelling of the Ocean (NEMO)) and the model 704 uses a learning-based PDE solver (e.g., neural operator) to approximate the evolution of sea surface height and storm surge. In an aspect, the traditional PDE solver may produce an exact solution and the learning-based PDE solver may produce an approximate solution.

In an aspect, machine learning or neural networks, e.g., in reduced order or Fourier space can be used with neural operators. For example, such machine learning or neural networks can approximate the simulated parameters in a high-resolution model of a multi-scale modeling system. In an embodiment, creating a surrogate of the SP with a neural operator allows for application across different mesh resolutions and parameter sets (e.g., changes in uncertain cloud physics parameters). In an embodiment, the high resolution parameters can be approximated, which may then be fed back to the low resolution model, which remains as modeled. In an aspect, the skill of a numerical modeling system can be retained for large scale dynamics as it simulates the low resolution system. Expensive high resolution simulations can be replaced with neural networks, e.g., which also operate in reduced order or Fourier space, to provide information at fine scales to the low resolution model. An improved representation of fine scale processes can be created where a multi-scale SP framework makes neural network training tractable.

In an aspect, learning the solution of physics-informed neural networks (PINNs) allows for flexibility, e.g., allowing for mesh-free interpolation in location, z. For example, the following illustrates such a model:

$$\frac{δ u \left(z , t\right)}{δ t} = a \left(t ; w\right) \frac{{δ}^{2}}{δ {z}^{2}} \left(u \left(z , t\right)\right) + ε$$

where,

$$\frac{δ u \left(z , t\right)}{δ t}$$

represents dynamics,
a(t; w) represents parameters,

$$\frac{{δ}^{2}}{δ {z}^{2}}$$
represents finite difference scheme,
u(z,t) represents a solution, and
∈ represents a parametrization or subgrid term.

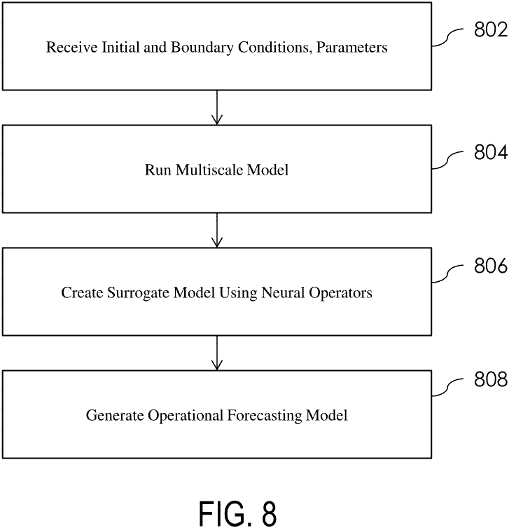

FIG. 8 is a flow diagram illustrating a method in an embodiment. The method can be run by or implemented on one or more computer processors, for example, hardware processors. One or more hardware processors, for example, may include components such as programmable logic devices, microcontrollers, memory devices, and/or other hardware components, which may be configured to perform respective tasks described in the present disclosure. Coupled memory devices may be configured to selectively store instructions executable by one or more hardware processors.

A processor may be a central processing unit (CPU), a graphics processing unit (GPU), a field programmable gate array (FPGA), an application specific integrated circuit (ASIC), another suitable processing component or device, or one or more combinations thereof. The processor may be coupled with a memory device. The memory device may include random access memory (RAM), read-only memory (ROM) or another memory device, and may store data and/or processor instructions for implementing various functionalities associated with the methods and/or systems described herein. The processor may execute computer instructions stored in the memory or received from another computer device or medium.

At 802, initial and boundary conditions, and parameters associated with geophysical modeling can be received. For example,

At 804, based on the received initial and boundary conditions and parameters, a multiscale model, e.g., coupled first resolution and second resolution models) can be run using a PDE solver for data generation to produce first resolution simulation data and second resolution simulation data for a surrogate machine learning model training. The second resolution simulation data has higher resolution than the first resolution simulation data.

At 806, a surrogate model can be created using neural operators, where the surrogate model is trained using the first resolution simulation data and second resolution simulation data.

At 808, an operational forecasting model can be generated using the surrogate model. In an aspect, the operational forecasting model functions as a partial differential equation solver that can work on a plurality of different multiscale modeling formulations. In an aspect, partial differential equations family is learned over all parameters using the neural operators. In an aspect, the amount of data, which may be required for neural operator training can be reduced by using super-parametrization. In an aspect, the surrogate model can capture features at a resolution higher than the first resolution simulation data.

In an embodiment, the trained surrogate model can be combined with an impact model for risk assessment. For instance, the impact model can include, but is not limited to, coastal flood prediction model. In an embodiment, based on a prediction, a processor may automatically trigger an actuator to control a physical device. For instance, processor may automatically trigger a physical or mechanical device, for example, such as opening and/or closing a physical flood barriers (e.g., storm surge barriers) automatically. Other devices can be automatically controlled based on a model’s prediction.

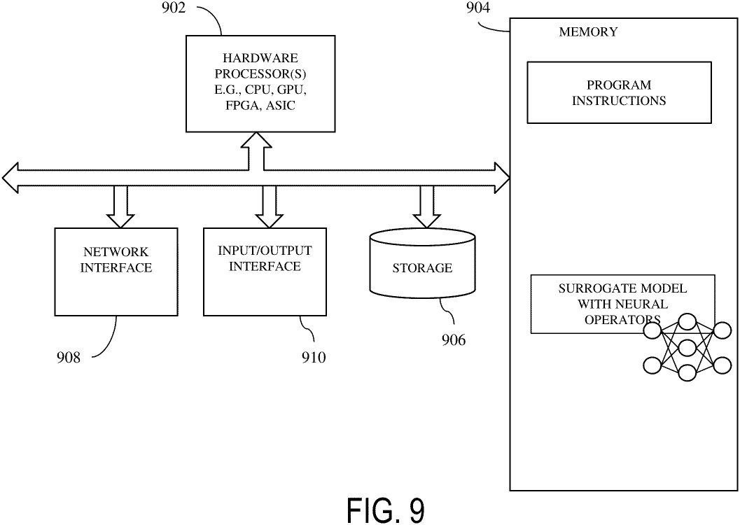

FIG. 9 is a diagram showing components of a system in one embodiment that can intelligently combine neural operators with super-parametrization to infer fine scale processes in multiscale models. One or more hardware processors 902 such as a central processing unit (CPU), a graphic process unit (GPU), and/or a Field Programmable Gate Array (FPGA), an application specific integrated circuit (ASIC), and/or another processor, may be coupled with a memory device 904, and generate a prediction model and recommend communication opportunities. A memory device 904 may include random access memory (RAM), read-only memory (ROM) or another memory device, and may store data and/or processor instructions for implementing various functionalities associated with the methods and/or systems described herein. One or more processors 902 may execute computer instructions stored in memory 904 or received from another computer device or medium. A memory device 904 may, for example, store instructions and/or data for functioning of one or more hardware processors 902, and may include an operating system and other program of instructions and/or data. One or more hardware processors 902 may receive input which may include initial and boundary conditions, and parameters, e.g., associated with geophysical modeling. For instance, one or more processors 902 may run a multiscale model, e.g., using a PDE solver, for data generation to produce first resolution simulation data and second resolution simulation data for a surrogate machine learning model training, where the second resolution simulation data has higher resolution than the first resolution simulation data. One or more processors 902 may create a surrogate model using neural operators. One or more processors 902 may generate an operational forecasting model using the surrogate model. In an aspect, input data and/or training data may be stored in a storage device 906 or received via a network interface 908 from a remote device, and may be temporarily loaded into a memory device 904 for building or generating the multiscale model, the surrogate model and/or the operational forecasting model. The learned models may be stored on a memory device 904, for example, for running by one or more hardware processors 902. One or more hardware processors 902 may be coupled with interface devices such as a network interface 908 for communicating with remote systems, for example, via a network, and an input/output interface 910 for communicating with input and/or output devices such as a keyboard, mouse, display, and/or others.

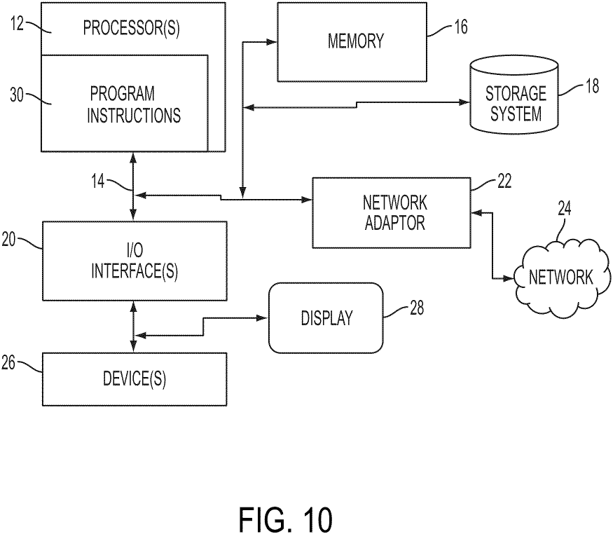

FIG. 10 illustrates a schematic of an example computer or processing system that may implement a system in one embodiment. The computer system is only one example of a suitable processing system and is not intended to suggest any limitation as to the scope of use or functionality of embodiments of the methodology described herein. The processing system shown may be operational with numerous other general purpose or special purpose computing system environments or configurations. Examples of well-known computing systems, environments, and/or configurations that may be suitable for use with the processing system shown in FIG. 10 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The computer system may be described in the general context of computer system executable instructions, such as program modules, being run by a computer system. Generally, program modules may include routines, programs, objects, components, logic, data structures, and so on that perform particular tasks or implement particular abstract data types. The computer system may be practiced in distributed cloud computing environments where tasks are performed by remote processing devices that are linked through a communications network. In a distributed cloud computing environment, program modules may be located in both local and remote computer system storage media including memory storage devices.

The components of computer system may include, but are not limited to, one or more processors or processing units 12, a system memory 16, and a bus 14 that couples various system components including system memory 16 to processor 12. The processor 12 may include a module 30 that performs the methods described herein. The module 30 may be programmed into the integrated circuits of the processor 12, or loaded from memory 16, storage device 18, or network 24 or combinations thereof.

Bus 14 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system may include a variety of computer system readable media. Such media may be any available media that is accessible by computer system, and it may include both volatile and non-volatile media, removable and non-removable media.

System memory 16 can include computer system readable media in the form of volatile memory, such as random access memory (RAM) and/or cache memory or others. Computer system may further include other removable/non-removable, volatile/non-volatile computer system storage media. By way of example only, storage system 18 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 14 by one or more data media interfaces.

Computer system may also communicate with one or more external devices 26 such as a keyboard, a pointing device, a display 28, etc.; one or more devices that enable a user to interact with computer system; and/or any devices (e.g., network card, modem, etc.) that enable computer system to communicate with one or more other computing devices. Such communication can occur via Input/Output (I/O) interfaces 20.

Still yet, computer system can communicate with one or more networks 24 such as a local area network (LAN), a general wide area network (WAN), and/or a public network (e.g., the Internet) via network adapter 22. As depicted, network adapter 22 communicates with the other components of computer system via bus 14. It should be understood that although not shown, other hardware and/or software components could be used in conjunction with computer system. Examples include, but are not limited to: microcode, device drivers, redundant processing units, external disk drive arrays, RAID systems, tape drives, and data archival storage systems, etc.

It is understood in advance that although this disclosure may include a description on cloud computing, implementation of the teachings recited herein are not limited to a cloud computing environment. Rather, embodiments of the present invention are capable of being implemented in conjunction with any other type of computing environment now known or later developed. Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service’s provider.

Broad network access: capabilities are available over a network and accessed through standard mechanisms that promote use by heterogeneous thin or thick client platforms (e.g., mobile phones, laptops, and PDAs).

Resource pooling: the provider’s computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider’s applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

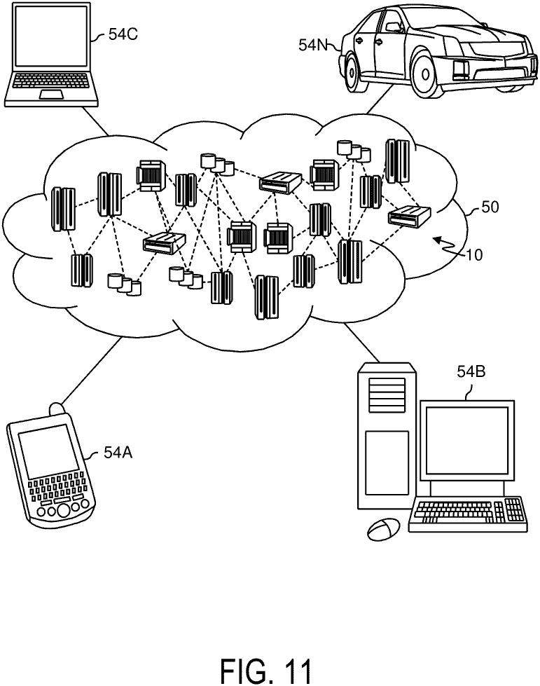

Referring now to FIG. 11, illustrative cloud computing environment 50 is depicted. As shown, cloud computing environment 50 includes one or more cloud computing nodes 10 with which local computing devices used by cloud consumers, such as, for example, personal digital assistant (PDA) or cellular telephone 54A, desktop computer 54B, laptop computer 54C, and/or automobile computer system 54N may communicate. Nodes 10 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 11 are intended to be illustrative only and that computing nodes 10 and cloud computing environment 50 can communicate with any type of computerized device over any type of network and/or network addressable connection (e.g., using a web browser).

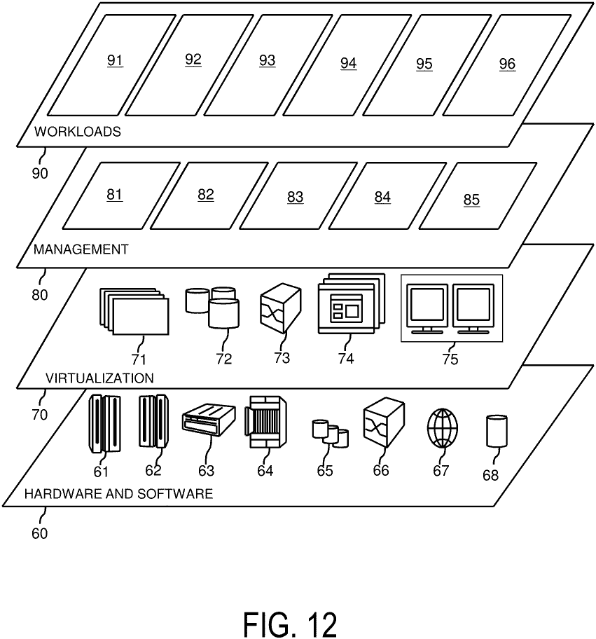

Referring now to FIG. 12, a set of functional abstraction layers provided by cloud computing environment 50 (FIG. 11) is shown. It should be understood in advance that the components, layers, and functions shown in FIG. 12 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and neural operators and super-parametrization processing 96.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, run concurrently, substantially concurrently, in a partially or wholly temporally overlapping manner, or the blocks may sometimes be run in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. As used herein, the term “or” is an inclusive operator and can mean “and/or”, unless the context explicitly or clearly indicates otherwise. It will be further understood that the terms “comprise”, “comprises”, “comprising”, “include”, “includes”, “including”, and/or “having,” when used herein, can specify the presence of stated features, integers, steps, operations, elements, and/or components, but do not preclude the presence or addition of one or more other features, integers, steps, operations, elements, components, and/or groups thereof. As used herein, the phrase “in an embodiment” does not necessarily refer to the same embodiment, although it may. As used herein, the phrase “in one embodiment” does not necessarily refer to the same embodiment, although it may. As used herein, the phrase “in another embodiment” does not necessarily refer to a different embodiment, although it may. Further, embodiments and/or components of embodiments can be freely combined with each other unless they are mutually exclusive.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A computer-implemented method comprising:
receiving initial and boundary conditions, and parameters associated with geophysical modeling;
based on the received initial and boundary conditions and parameters, running a multiscale model for data generation to produce first resolution simulation data and second resolution simulation data for a surrogate machine learning model training, wherein the second resolution simulation data has higher resolution than the first resolution simulation data;
creating a surrogate model using neural operators, wherein the surrogate model is trained using the first resolution simulation data and second resolution simulation data; and
generating an operational forecasting model using the surrogate model.

2. The method of claim 1, wherein the operational forecasting model functions as a partial differential equation solver that can work on a plurality of different multiscale modeling formulations.

3. The method of claim 1, wherein partial differential equations family is learned over all parameters using the neural operators.

4. The method of claim 1, wherein an amount of data needed for neural operator training is reduced by using super-parametrization.

5. The method of claim 1, wherein the surrogate model captures features at a resolution higher than the first resolution simulation data.

6. The method of claim 1, further including combining the trained surrogate model with an impact model for risk assessment.

7. The method of claim 6, wherein the impact model includes coastal flood prediction model, the first resolution simulation data and the second resolution simulation data can include at least data associated sea surface height, and the method further includes triggering a physical barrier to open or close.

8. A computer program product comprising a computer readable storage medium having program instructions embodied therewith, the program instructions readable by a device to cause the device to:
receive initial and boundary conditions, and parameters associated with geophysical modeling;
based on the received initial and boundary conditions and parameters, run a multiscale model for data generation to produce first resolution simulation data and second resolution simulation data for a surrogate machine learning model training, wherein the second resolution simulation data has higher resolution than the first resolution simulation data;
create a surrogate model using neural operators, wherein the surrogate model is trained using the first resolution simulation data and second resolution simulation data; and
generate an operational forecasting model using the surrogate model.

9. The computer program product of claim 8, wherein the operational forecasting model functions as a partial differential equation solver that can work on a plurality of different multiscale modeling formulations.

10. The computer program product of claim 8, wherein partial differential equations family is learned over all parameters using the neural operators.

11. The computer program product of claim 8, wherein an amount of data needed for neural operator training is reduced by using super-parametrization.

12. The computer program product of claim 8, wherein the surrogate model captures features at a resolution higher than the first resolution simulation data.

13. The computer program product of claim 8, wherein the device is further caused to combine the trained surrogate model with an impact model for risk assessment.

14. The computer program product of claim 13, wherein the impact model includes coastal flood prediction model.

15. A system comprising:
a processor; and
a memory device coupled with the processor,
the processor configured to at least:
receive initial and boundary conditions, and parameters associated with geophysical modeling;
based on the received initial and boundary conditions and parameters, run a multiscale model for data generation to produce first resolution simulation data and second resolution simulation data for a surrogate machine learning model training, wherein the second resolution simulation data has higher resolution than the first resolution simulation data;
create a surrogate model using neural operators, wherein the surrogate model is trained using the first resolution simulation data and second resolution simulation data; and
generate an operational forecasting model using the surrogate model.

16. The system of claim 15, wherein the operational forecasting model functions as a partial differential equation solver that can work on a plurality of different multiscale modeling formulations.

17. The system of claim 15, wherein partial differential equations family is learned over all parameters using the neural operators.

18. The system of claim 15, wherein an amount of data needed for neural operator training is reduced by using super-parametrization.

19. The system of claim 15, wherein the surrogate model captures features at a resolution higher than the first resolution simulation data.

20. The computer program product of claim 8, wherein the processor is further configured to combine the trained surrogate model with an impact model for risk assessment.
